(19) United States
(12) Patent Application Publication
(10) Pub. No.: US 2025/0296328 A1
(43) Pub. Date: Sep. 25, 2025

(54) ACTUATOR, LIQUID DISCHARGE HEAD, LIQUID DISCHARGE UNIT, LIQUID DISCHARGE APPARATUS, AND ULTRASONIC DIAGNOSTIC APPARATUS

(71) Applicant: Toshiaki MASUDA, Kanagawa (JP)

(72) Inventor: Toshiaki MASUDA, Kanagawa (JP)

(21) Appl. No.: 19/077,067

(22) Filed: Mar. 12, 2025

(30) Foreign Application Priority Data
Mar. 22, 2024 (JP) 2024-046910

(51) Int. Cl. B41J 2/14; G01N 29/04; G01N 29/24; H10N 30/20

(52) U.S. Cl. CPC B41J 2/14233; G01N 29/04; G01N 29/2437; H10N 30/2047

(57) ABSTRACT

An actuator includes a substrate, a frame, and a projection. The substrate has a first bonding face. The substrate includes a diaphragm, a piezoelectric body over the diaphragm to generate driving force to vibrate the diaphragm, and at least two electrodes sandwiching the piezoelectric body to apply voltage to the piezoelectric body. The frame has a second bonding face bonded to the first bonding face of the substrate in a bonding direction to hold the substrate. The projection projects in the bonding direction from at least one of the first bonding face or the second bonding face to restrict a distance between the first bonding face of the substrate and the second bonding face of the frame. The projection has a height in the bonding direction. The height of the projection varies toward a periphery of the frame in at least one of a longitudinal direction or a transverse direction.

### CROSS-REFERENCE TO RELATED APPLICATION

This patent application is based on and claims priority pursuant to 35 U.S.C. § 119 (a) to Japanese Patent Application No. 2024-046910, filed on Mar. 22, 2024, in the Japan Patent Office, the entire disclosure of which is hereby incorporated by reference herein.

### BACKGROUND

### Technical Field

The present disclosure relates to an actuator, a liquid discharge head, a liquid discharge unit, a liquid discharge apparatus, and an ultrasonic diagnostic apparatus.

### Related Art

An actuator including a thin-film piezoelectric body is used, for example, for a liquid discharge head.

### SUMMARY

The present disclosure described herein provides an improved actuator including a substrate, a frame, and a projection. The substrate has a first bonding face. The substrate includes a diaphragm, a piezoelectric body over the diaphragm to generate driving force to vibrate the diaphragm, and at least two electrodes sandwiching the piezoelectric body to apply voltage to the piezoelectric body to generate the driving force. The frame has a second bonding face bonded to the first bonding face of the substrate in a bonding direction to hold the substrate. The projection projects in the bonding direction from at least one of the first bonding face or the second bonding face to restrict a distance between the first bonding face of the substrate and the second bonding face of the frame. The projection has a height in the bonding direction. The height of the projection varies toward a periphery of the frame in at least one of a longitudinal direction of the substrate orthogonal to the bonding direction or a transverse direction orthogonal to the longitudinal direction and the bonding direction.

Further, the present disclosure described herein provides an improved actuator including a substrate and a frame. The substrate has a first bonding face. The substrate includes a diaphragm, a piezoelectric body over the diaphragm to generate driving force to vibrate the diaphragm, and two electrodes sandwiching the piezoelectric body to apply voltage to the piezoelectric body to generate the driving force. The frame has a second bonding face bonded to the first bonding face of the substrate in a bonding direction to hold the substrate. At least one of the first bonding face or the second bonding face has a curved shape (or multiple sloped shapes).

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram illustrating a configuration of a liquid discharge head;

FIG. 2 is another schematic diagram illustrating a configuration of a liquid discharge head;

FIG. 3 is a diagram illustrating pressurizers arranged on an actuator substrate;

FIG. 4 is a schematic diagram of an actuator including a vibration generating substrate and a frame bonded to each other according to a comparative example;

FIG. 5 is a schematic diagram of an actuator including a vibration generating substrate and a frame bonded to each other according to an embodiment of the present disclosure;

FIG. 6A is a schematic diagram of a vibration generating substrate, which warps in a direction different from the warpage illustrated in FIG. 4, and a frame according to a comparative example;

FIG. 6B is a schematic diagram of a vibration generating substrate and a frame according to an embodiment of the present disclosure;

FIG. 7 is a schematic diagram of a projection on a frame;

FIG. 8A is a schematic diagram of a frame having a tapered shape;

FIG. 8B is a schematic diagram of a frame having a curved shape;

FIG. 9 is a diagram illustrating a configuration of an inkjet recording apparatus including a liquid discharge head;

FIG. 10 is a schematic diagram of an electrode manufacturing apparatus as a liquid discharge apparatus;

FIG. 11 is a schematic diagram of an ultrasonic diagnostic apparatus including an actuator;

FIG. 12 is a schematic diagram illustrating a configuration of an ultrasonic probe;

FIG. 13 is a cross-sectional view of an actuator; and

FIGS. 14A to 14C are other schematic diagrams of a vibration generating substrate and a frame.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

An actuator including a thin-film piezoelectric body is used, for example, for a liquid discharge head. In the liquid discharge head including such an actuator, the actuator may structurally warp, or the actuator bonded to a different component with an adhesive may warp due to the influence of the difference in thermal expansion coefficient or the influence of contraction stress of the adhesive. Stress caused by such a warpage may change the rigidity of a diaphragm that generates pressure, resulting in variations in discharge characteristics.

Embodiments of the present disclosure are described below with reference to the attached drawings. In the drawings for illustrating embodiments of the present disclosure, like elements or like components in function or shape are given like reference signs as far as distinguishable, and overlapping descriptions may be omitted.

According to the present disclosure, an actuator includes a substrate, a different component, and a projection. The substrate includes a diaphragm and has a function of vibrating the diaphragm. The substrate may be referred to as the “substrate” or a “vibration generating substrate.” The different component holds the above-described substrate. The substrate and the different component are bonded to each other via a bonding face. The projection is formed on the bonding face of the substrate or the different component. Thus, the substrate after bonding can be prevented from warping. The projection acts as a restrictor having a shape that restricts the distance between the substrate and the different component. Examples of the different component includes a frame. The different component may be referred to as the “frame” as appropriate in the following description.

An actuator according to an embodiment of the present disclosure includes a projection formed on the surface of the substrate or the surface of the frame to be bonded to the substrate to compensate for stress imposed on the substrate in an in-plane direction of the surface. After the formation of the projection, the substrate and the frame are bonded to each other. Thus, the influence of the stress due to the difference in thermal expansion coefficient between components can be mechanically compensated, so that the stress imposed on the substrate can be controlled in the in-plane direction of the substrate. For example, a liquid discharge head including such an actuator can control variations in discharge characteristics.

The warpage of the substrate has a single convex shape or concave shape in the longitudinal direction or transverse direction of the actuator. Thus, to compensate for the warpage, preferably, the distance between the substrate and the frame (distance between the bonding face of the substrate and the bonding face of the frame) decreases gradually or increases gradually from the center of the substrate or the frame toward the end of the substrate or the frame in the longitudinal direction or transverse direction. In other words, the height of the projection decreases gradually or increases gradually from the center of the substrate or the frame toward the end of the substrate or the frame in the longitudinal direction or transverse direction.

Detailed descriptions will be given below with reference to the drawings.

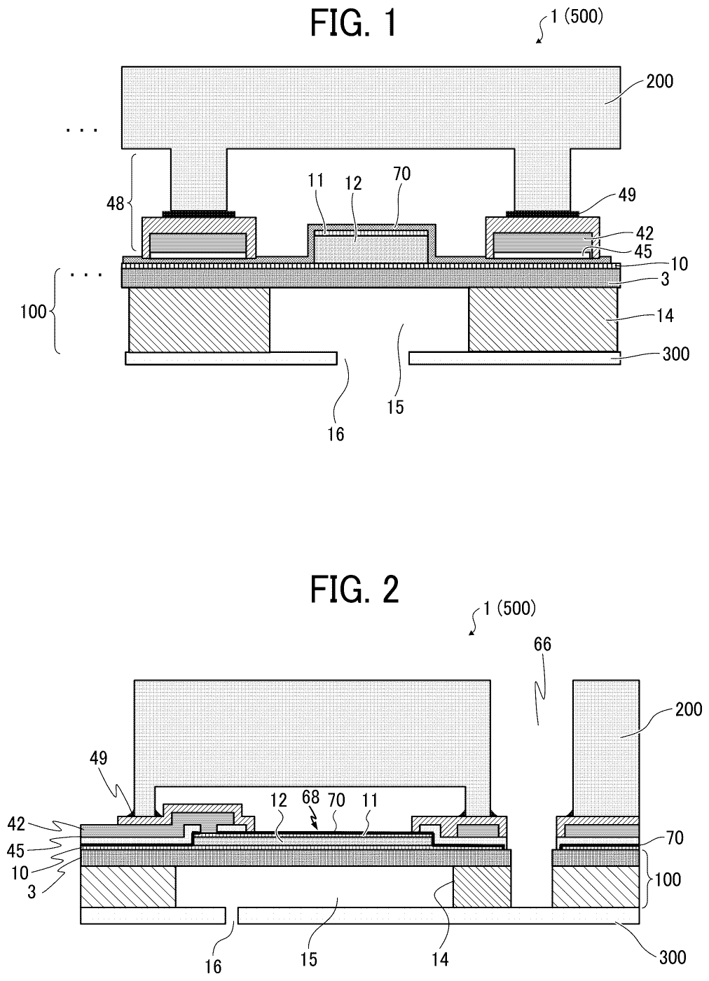

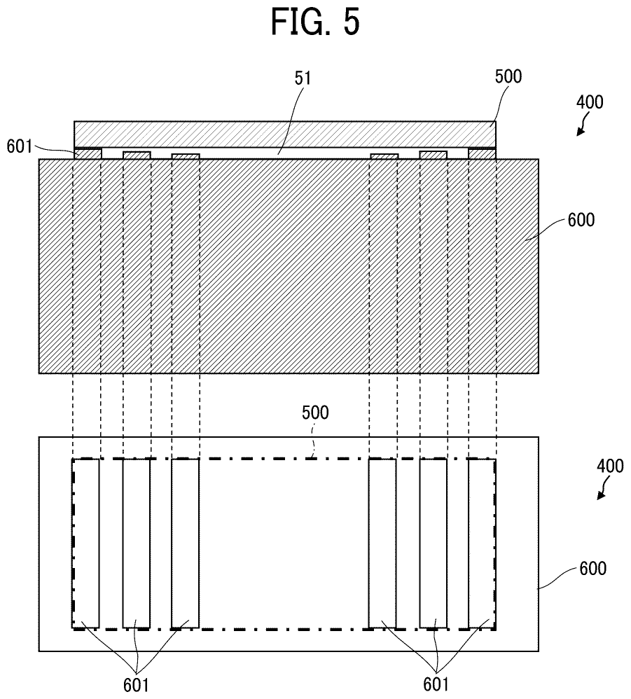

FIG. 1 is a schematic diagram illustrating a configuration of a liquid discharge head, which may be referred to as an “inkjet head.” FIG. 1 illustrates a cross section of a part of the liquid discharge head in the longitudinal direction of a pressure chamber. The part of the liquid discharge head in FIG. 1 corresponds to a substrate (e.g., a vibration generating substrate 500) to be described later, for example, with reference to FIG. 5.

As illustrated in FIG. 1, a liquid discharge head 1 includes an actuator substrate 100, a support substrate 200, and a nozzle substrate 300. The liquid discharge head 1 further includes a frame bonded to the support substrate 200. The liquid discharge head 1 further includes a diaphragm 3 and a piezoelectric body 12 over the diaphragm 3 in the actuator substrate 100. The piezoelectric body 12 generates energy (i.e., driving force) to vibrate the diaphragm 3 to discharge liquid. The piezoelectric body 12 may be referred to as a “piezoelectric element,” and the diaphragm 3 may be referred to as a “vibration film.” The actuator substrate 100 defines pressure chamber partitions 14 and pressure chambers 15. The pressure chamber 15 may be referred to as an “individual liquid chamber.”

The piezoelectric body 12 is sandwiched between a common electrode 10, which may be referred to as a “first electrode,” and an individual electrode 11, which may be referred to as a “second electrode.” A wiring layer 42, which may be referred to as a “leading wire,” is laminated on the layer of each electrode to apply voltage to the piezoelectric body 12 by the common electrode 10 and the individual electrode 11 (i.e., two electrodes).

The pressure chambers 15 are separated by the corresponding pressure chamber partitions 14. The pressure chambers 15 are defined by the actuator substrate 100 and the nozzle substrate 300 having a nozzle hole 16 (may be referred to simply as a nozzle). Another substrate defining a channel may be disposed between the actuator substrate 100 and the nozzle substrate 300 to rectify the flow of ink.

The actuator substrate 100, the support substrate 200, and the nozzle substrate 300 are bonded to one on another to form the liquid discharge head 1.

In the liquid discharge head 1 formed as above, when the pressure chamber 15 is filled with liquid, such as recording liquid (ink), an oscillator circuit applies, for example, a pulse voltage of 20 V to the individual electrode 11 corresponding to the nozzle hole 16, from which the recording liquid is to be discharged, through the wiring layer 42 and a connection hole formed through an interlayer insulating film 45, based on image data from a controller. Due to electrostrictive effect based on the application of such a pulse voltage, the corresponding piezoelectric body 12 contracts parallel to the diaphragm 3, so that the diaphragm 3 bends in the longitudinal direction of the pressure chamber 15.

Thus, the pressure in the pressure chamber 15 rapidly rises, so that the recording liquid is discharged through the nozzle hole 16 communicating with the pressure chamber 15. After the application of the pulse voltage, the bent diaphragm 3 returns to the original position because the contracted piezoelectric body 12 returns to the initial shape. Thus, the pressure of the recording liquid in the pressure chamber 15 is less than that in a common liquid chamber, so that the ink supplied from outside through a liquid supply port is supplied to the pressure chamber 15. Repetition of such operation causes the liquid discharge head 1 to discharge droplets of the recording liquid sequentially to form an image on a recording medium (sheet) disposed opposite the liquid discharge head 1.

The manufacturing process of the liquid discharge head 1 will be described below with reference to FIG. 2.

First, as the actuator substrate 100, the diaphragm 3 is formed on a silicon single crystal substrate having plane orientation (110). For example, the silicon single crystal substrate has a thickness of 400 μm. The diaphragm 3 has a structure in which a silicon oxide film and a silicon nitride film are layered as materials, for example, by low-pressure chemical vapor deposition (LP-CVD). For the diaphragm 3, other materials such as silicon and zircon oxide may be used or other elements may be doped for stress control. Alternatively, an active layer in a silicon-on-insulator (SOI) wafer may be used or formed. The plane orientation of the silicon substrate is not limited to (110), and thus, preferably, a plane orientation suitable for flow in a subsequent process can be selected.

Then, a film of platinum (Pt) having a thickness of 150 nm and a film of titanium dioxide (TiO₂) having a thickness of 40 nm are formed by sputtering to form the common electrode 10, and a film of lead zirconate titanate (PZT) having a thickness of 2 μm is formed by a plurality of times of spin coating to form the piezoelectric body 12. A film of strontium ruthenate (SRO) having a thickness of 40 nm and a film of Pt having a thickness of 100 nm are formed by sputtering to form the individual electrode 11 (upper electrode). A method for forming the piezoelectric body 12 is not limited to a sol-gel method with spin coating and thus may be, for example, sputtering, ion plating, an aerosol method, or an inkjet method.

The material for the electrode may be, for example, Pt, titanium (Ti), gold (Au), or copper (Cu). The piezoelectric body 12 formed by the sol-gel method will be described below. A PZT precursor is layered over the Pt film and then is fired. In this case, the firing is performed, for example, in three steps of drying (at 120° C.), calcining (at 380° C.), and firing (at 700° C.). Thus, the piezoelectric body 12 on the common electrode 10 can have favorable crystallinity having PZT with plane orientation (100). The piezoelectric body 12 and the individual electrode 11 are formed, by lithography etching, at a position corresponding to the pressure chamber 15 to be formed later.

Subsequently, for example, a film of titanium nitride (TiN) having a thickness of 30 nm and a film of aluminum (Al) having a thickness of 3 μm are formed by sputtering to form the wiring layer 42. When Pt, which is the material for the individual electrode 11 or the common electrode 10, directly contacts Al, which is the material for the wiring layer 42, at a connection with the common electrode 10 or a connection with the individual electrode 11, Pt may be alloyed by heat history in a subsequent step. TiN is used to prevent, for example, film peeling due to stress caused by volume change of the films. Preferably, a low-resistance material is used for the wiring layer 42. A material containing Au, nickel (Ni), or chromium (Cr) may be used to form the wiring layer 42. Further, to prevent water from entering the piezoelectric body 12, for example, a film of aluminum oxide (Al₂O₃) having a thickness of 700 nm is formed as a barrier layer 70 by chemical vapor deposition (CVD) or atomic layer deposition (ALD). In FIGS. 1 and 2, although the individual electrode 11 functions as an upper electrode and the common electrode 10 functions as a lower electrode, the functions thereof may be reversed. The piezoelectric body 12 is connected to two different electrodes.

Then, the support substrate 200 having a counterbore (recess) is produced. The counterbore is formed at a position corresponding to an actuator portion 68 by lithography etching. In this case, silicon (Si) processing is performed by dry etching. After that, the support substrate 200 and the actuator substrate 100 are bonded to each other with an adhesive 49 via a joint 48. In this case, the adhesive 49 having a thickness of approximately 1 μm is applied to the support substrate 200 by a typical thin-film transfer device. After that, the actuator substrate 100 is polished by a commonly used technique so as to have a desired thickness (e.g., a thickness of 80 μm) to form the pressure chamber 15. Instead of polishing, etching may be used.

A liquid-chamber formation layer is covered with resist by lithography. After that, the pressure chamber 15 is formed by anisotropic wet etching with an alkaline solution, such as potassium hydroxide (KOH) solution or tetramethyl ammonium hydroxide (TMAH) solution. The pressure chamber 15 may be formed by dry etching using an inductively coupled plasma (ICP) etcher, instead of the anisotropic etching using an alkaline solution. The nozzle substrate 300 separately formed, in which the nozzle hole 16 is opened at the position corresponding to the pressure chamber 15, is bonded to the actuator substrate 100.

The frame made of a glass epoxy resin is bonded to one face of the support substrate 200 opposite the other face to which the actuator substrate 100 is bonded to complete the liquid discharge head 1. The frame has a channel for introducing ink to the actuator substrate 100. The material for the frame is not limited to the glass epoxy resin. When thermal curing is performed for bonding, a material with small difference in thermal expansion coefficient from silicon is preferably used as the material for the frame. Silicon is used as the base material for the actuator substrate 100. For example, a damper made of palladium-nickel (PdNi) alloy and a damper frame formed of Si to hold the damper may be joined between the actuator substrate 100 and the frame. In addition to the above description, an ink supply port 66 is formed.

By the above-described process, for example, a pressurizer including the diaphragm 3, the common electrode 10, the piezoelectric body 12, the individual electrode 11, and the wiring layer 42 are formed in the actuator substrate 100.

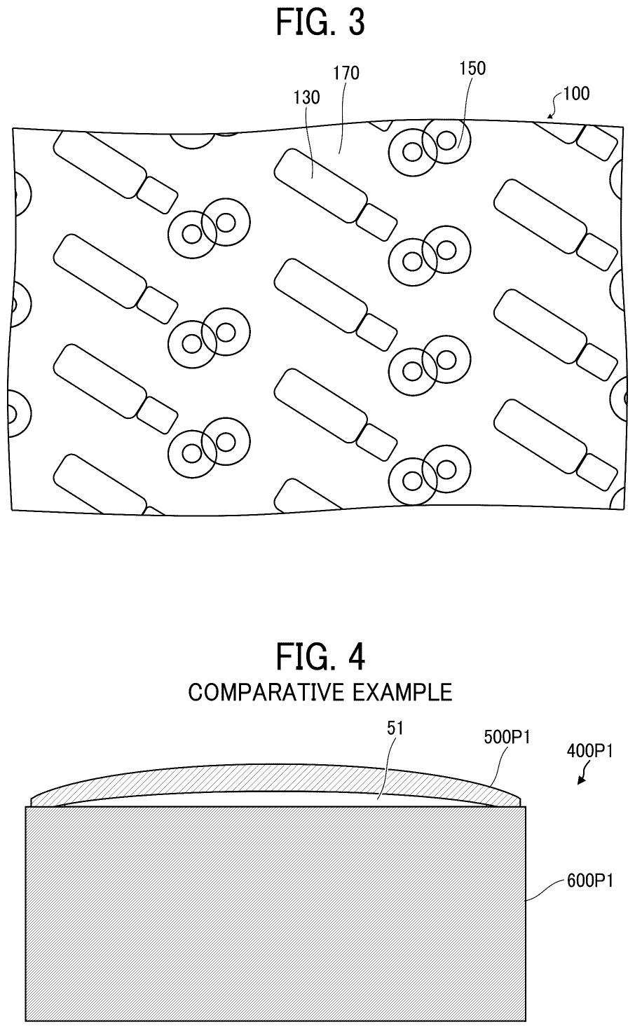

FIG. 3 is a diagram illustrating pressurizers arranged in the actuator substrate 100. FIG. 3 illustrates the bonding face of the actuator substrate 100 to which the support substrate 200 is to be bonded.

The components described with reference to FIGS. 1 and 2, such as the diaphragm 3, the common electrode 10, the piezoelectric body 12, the individual electrode 11, and the wiring layer 42, are disposed in a region 130. For example, the ink supply port 66 is formed in a region 150. As illustrated in FIG. 3, the actuator substrate 100 has multiple regions 130 and multiple regions 150. For example, a channel or a wiring layer is disposed in a region 170 out of the regions 130 and the regions 150. The characteristics of the actuator substrate 100 produced by the process as described above will be described below.

The actuator substrate 100 before being bonded to the frame has a certain amount of warpage caused by the inner stress of the respective films in the substrate and the bonding process. The amount of warpage indicates that stress is applied to the actuator substrate 100. Accordingly, the rigidity of the pressurizer disposed above the pressure chamber 15 is changed by the stress.

In an inkjet head, a voltage waveform is input based on a resonance frequency to vibrate the pressurizer to discharge ink. The resonance frequency is determined, for example, by the above-described pressurizer, the pressure chamber 15, the dimensions between the pressure chamber 15 and the common liquid chamber for supplying the ink to the pressure chamber 15, and the ink to be used. Accordingly, as the rigidity of the pressurizer is changed by the stress as described above, the resonance frequency is changed. Thus, desired discharge characteristics may not be obtained. Further, stress is generated in the actuator substrate 100 by the difference in the thermal expansion coefficient from the frame.

Features of an actuator including the above-described actuator substrate 100 and the frame according to an embodiment of the present disclosure will be described below with reference to a comparative example.

For example, an actuator includes a vibration generating substrate and a frame. The vibration generating substrate is a substrate including at least a diaphragm (the diaphragm 3), a piezoelectric body (the piezoelectric body 12) that generates driving force, and two electrodes (the common electrode 10 and the individual electrode 11) that cause the piezoelectric body to generate the driving force. The frame is bonded to the vibration generating substrate to hold the vibration generating substrate. The names and reference numerals written in the parentheses correspond to components illustrated in FIGS. 1 and 2, respectively. The vibration generating substrate may include the support substrate 200 described above or may not include the support substrate 200.

FIG. 4 is a schematic diagram of an actuator including a vibration generating substrate and a frame bonded to each other according to a comparative example. FIG. 5 is a schematic diagram of an actuator including a vibration generating substrate and a frame bonded to each other according to an embodiment of the present disclosure.

FIG. 4 schematically illustrates a cross section in a lamination direction (i.e., a bonding direction) of an actuator 400P1 including a vibration generating substrate 500P1 and a frame 600P1 that are bonded to each other with an adhesive 51. The upper part of FIG. 5 schematically illustrates a cross section in the lamination direction of an actuator 400 including a vibration generating substrate 500 and a frame 600 that are bonded to each other with the adhesive 51. The lower part of FIG. 5 is a plan view corresponding to the cross-sectional view of the upper part of FIG. 5.

As illustrated in FIG. 4, when the vibration generating substrate 500P1 and the frame 600P1 having a flat and smooth bonding face to be bonded to the vibration generating substrate 500P1 are bonded to each other, the center of the vibration generating substrate 500P1 warps in a direction away from the frame 600P1 after bonding.

On the other hand, as illustrated in FIG. 5, the actuator 400 includes projections 601 on the bonding face of the frame 600 to which the vibration generating substrate 500 is bonded to prevent the vibration generating substrate 500 from warping. The heights of the projections 601 increase toward the periphery of the frame 600. As a result, the peripheral portion of the vibration generating substrate 500 is pressed upward in FIG. 5, so that the warpage of the vibration generating substrate 500 after bonding becomes small.

The lower part of FIG. 5 is a plan view of the bonding face of the frame 600 to which the actuator substrate 100 is to be bonded. The position of the actuator substrate 100 to be bonded is indicated by the dashed-dotted line in FIG. 5, and the projections 601 are colored gray.

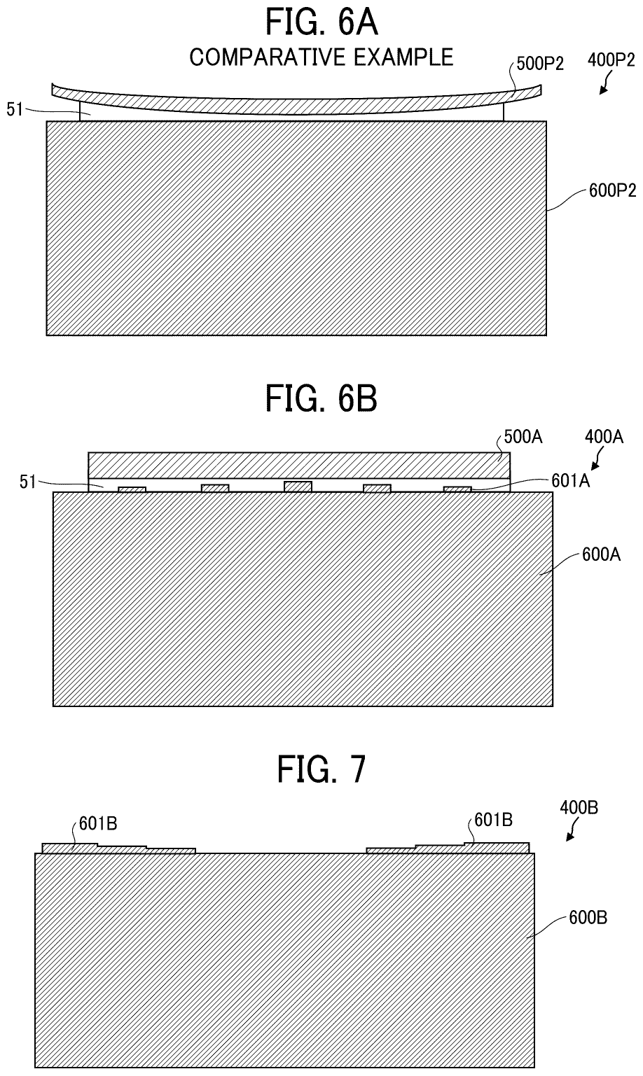

FIGS. 6A and 6B each illustrate a vibration generating substrate that warps in a different direction from the warpage illustrated in FIG. 4. FIG. 6A illustrates an actuator 400P2 including a vibration generating substrate 500P2 and a frame 600P2 according to a comparative example. FIG. 6B illustrates an actuator 400A including a vibration generating substrate 500A and a frame 600A according to an embodiment of the present disclosure.

Depending on the direction of the warpage of the vibration generating substrate, as illustrated in FIG. 6B, the frame 600A may have projections 601A having heights that decrease toward the periphery of the frame 600A.

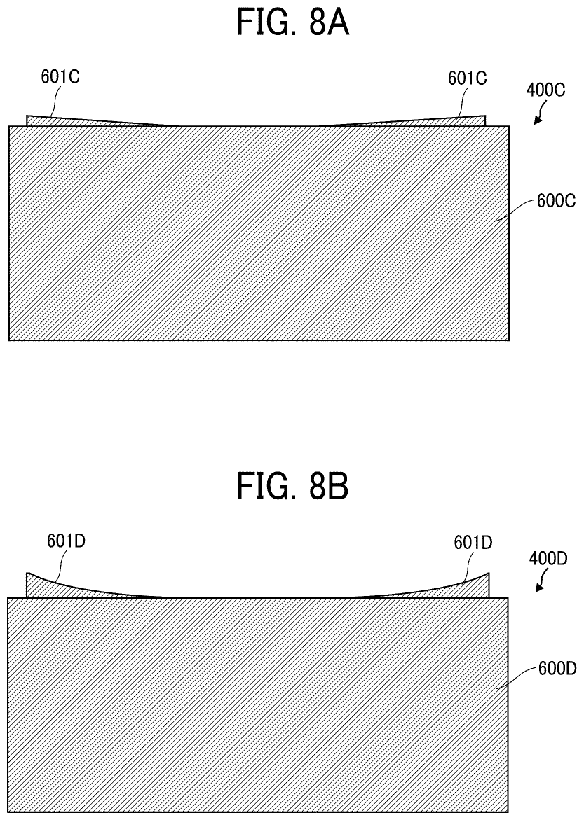

In FIGS. 5 and 6B, the projections 601 are discontinuous on a plane parallel to the bonding face of the frame 600, and the projections 601A are discontinuous on a plane parallel to the bonding face of the frame 600A. Alternatively, as illustrated in FIG. 7, projections 601B on a frame 600B of an actuator 400B each may be a continuous projection (e.g., a stepwise-shaped projection). Instead of the stepwise-shaped projection, as illustrated in FIG. 8A or 8B, projections 601C on a frame 600C of an actuator 400C each may have a tapered shape (sloped shape) or projections 601D on a frame 600D of an actuator 400D each may have a curved shape.

Projections are disposed at least between a vibration generating substrate and a frame. Thus, the projections may be disposed on a vibration generating substrate (e.g., the support substrate 200). When another additional substrate is disposed between the vibration generating substrate and the frame, projections may be disposed on the additional substrate.

The projections having various shapes have been described with reference to FIGS. 5 to 8B, but the shapes of the projections are not limited thereto. For example, a projection may have a recess having a recessed shape.

For example, the vibration generating substrate 500 has the bonding face (i.e., a first bonding face) to which the frame 600 is bonded, and the frame 600 has the bonding face (i.e., a second bonding face) to which the vibration generating substrate 500 is bonded. Preferably, a projection is disposed on at least one of the bonding face of the vibration generating substrate 500 or the bonding face of the frame 600.

Due to the projection, preferably, the distance between the vibration generating substrate 500 and the frame 600 varies toward the periphery of the vibration generating substrate 500 or the frame 600. For example, due to the projection, preferably, the distance described above varies in at least one of a first direction of the actuator (e.g., the longitudinal direction) or a second direction of the actuator (e.g., the transverse direction) intersecting the first direction.

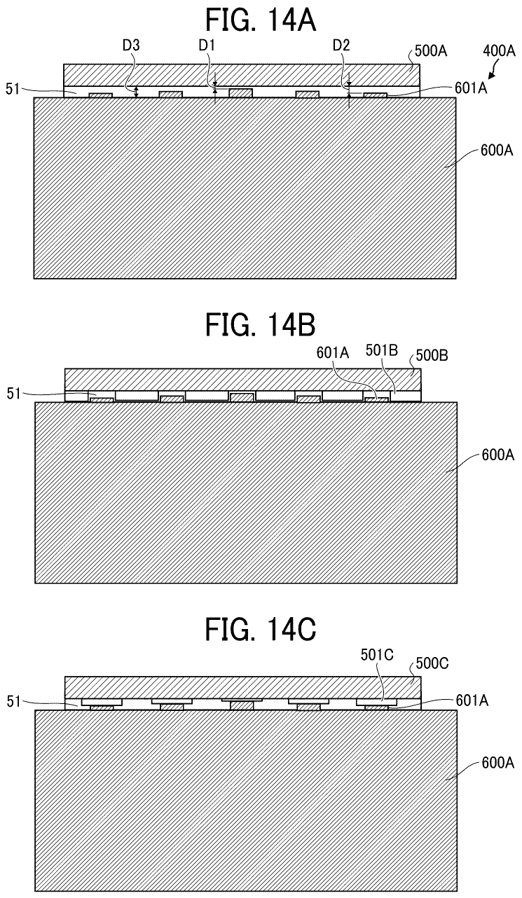

For example, with reference to FIG. 14A, a distance D1 between the vibration generating substrate 500A and the frame 600A at a central portion is different from a distance D2 between the vibration generating substrate 500A and the frame 600A at an outer portion. Further, the distances D1 and D2 between the vibration generating substrate 500A and the frame 600A at the central portion and at the outer portion are different from a distance D3 between the vibration generating substrate 500A and the frame 600A at another portion excluding the central portion and the outer portion.

As illustrated in FIGS. 5 and 6B, multiple projections have different heights such that the distance described above varies stepwise. Alternatively, as illustrated in FIG. 7, the projection may have a continuous stepwise shape (i.e., the height of the projection varies stepwise) such that the distance described above varies stepwise. Preferably, the projection has at least one of a tapered shape (sloped shape), a curved shape, or a stepwise shape. For example, as illustrated in FIG. 8A or 8B, the projection may have the tapered shape or the curved shape such that the distance described above (i.e., the height of the curved shape or tapered shape) varies toward the periphery. For example, the projection may have a combination of at least two of a tapered shape, a curved shape, or a stepwise shape.

The projection may be disposed on both the vibration generating substrate 500 and the frame 600. For example, with reference to FIG. 14B, projections 501B of a vibration generating substrate 500B and the projections 601A of the frame 600A may be fitted to each other to bond the vibration generating substrate 500B and the frame 600A. Alternatively, with reference to FIG. 14C, projections 501C (i.e., a first projection) of a vibration generating substrate 500C may face the projections 601A (i.e., a second projection) of the frame 600A, and the projections 501C of the vibration generating substrate 500C may be bonded to the projections 601A of the frame 600A to bond the vibration generating substrate 500C and the frame 600A.

According to the above-described actuators, the warpage of a substrate and a different component after bonding is controlled. The substrate includes a diaphragm and has a function of vibrating the diaphragm. As a result, an inkjet head and an inkjet recording apparatus can be provided that has, for example, good uniformity of discharge characteristics in the in-plane direction.

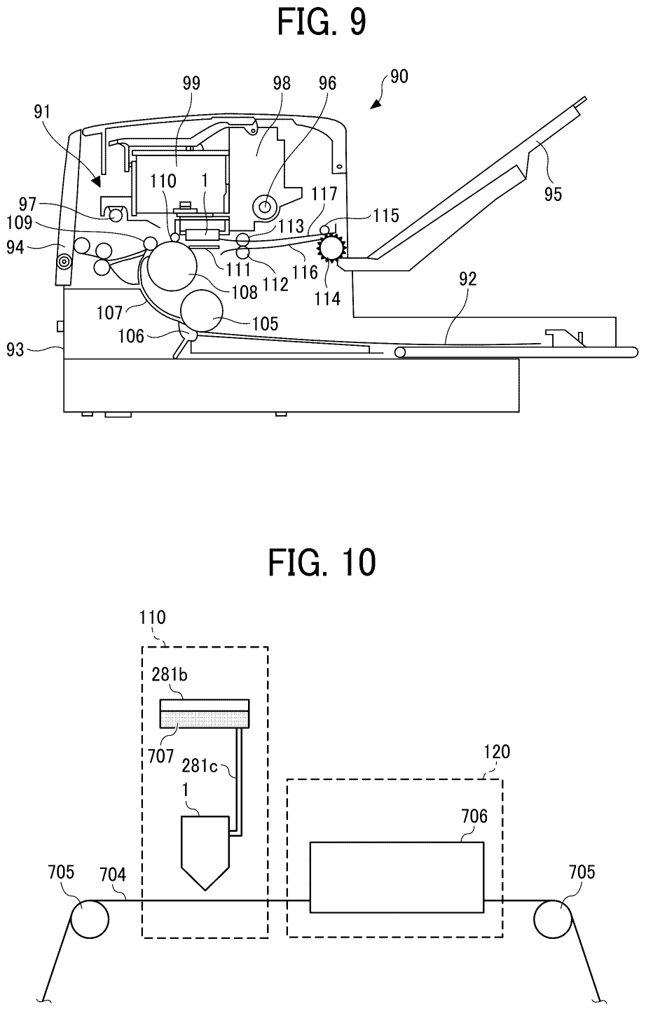

FIG. 9 illustrates an inkjet recording apparatus 90 as a liquid discharge apparatus on which the liquid discharge head 1 including the above-described actuator is mounted. The inkjet recording apparatus 90 houses a printing mechanism 91 (i.e., a liquid discharge unit) including a carriage 98, a liquid discharge head 1, and an ink cartridge 99 in the apparatus body thereof. The carriage 98 is movable in a main scanning direction to move the liquid discharge head 1. The liquid discharge head 1 and the ink cartridge 99 are mounted on the carriage 98. The ink cartridge 99 supplies ink to the liquid discharge head 1. A sheet feeding cassette (or sheet feeding tray) 93 is detachably attached to the lower portion of the apparatus body from the front side. A plurality of sheets 92 is loaded on the sheet feeding cassette 93. The inkjet recording apparatus 90 includes a bypass feeder 94 openable for manually feeding sheets 92. The inkjet recording apparatus 90 takes in a sheet 92 (i.e., a medium) fed from the sheet feeding cassette 93 or the bypass feeder 94, records a desired image on the sheet 92 by the printing mechanism 91, and then ejects the sheet 92 to a sheet ejection tray 95 attached to the rear side of the apparatus body.

The printing mechanism 91 holds a main guide rod 96 and a sub-guide rod 97, which are guides bridged laterally between a left side plate and a right side plate, and holds the carriage 98 slidably in the main scanning direction. The liquid discharge heads 1 that discharge droplets of color inks of yellow (Y), cyan (C), magenta (M), and black (Bk) are mounted on the carriage 98 such that multiple ink discharge ports (nozzles) are arrayed in a direction intersecting the main scanning direction to discharge the ink droplets downward. Ink cartridges 99 that supply the respective color inks to the liquid discharge heads 1 are replaceably attached to the carriage 98.

Each of the ink cartridges 99 has an atmosphere communication port, a supply port, and a porous body. The atmosphere communication port is disposed at an upper portion of each ink cartridge 99 to communicate with the atmosphere. The supply port is disposed at a lower portion of each ink cartridge 99 to supply ink to the liquid discharge heads 1. The porous body is disposed inside each ink cartridge 99 to be filled with ink. Ink to be supplied to the liquid discharge heads 1 is kept at a slight negative pressure by capillary force of the porous body. In the present embodiment, the liquid discharge heads 1 discharge droplets of the respective color inks. In some embodiments, a single liquid discharge head that has nozzles to discharge droplets of different color inks may be used.

The rear side (the downstream side in a sheet conveyance direction) of the carriage 98 is slidably fitted onto the main guide rod 96, and the front side (the upstream side in the sheet conveyance direction) of the carriage 98 is slidably mounted onto the sub-guide rod 97. In order to move the carriage 98 in the main scanning direction, a timing belt is stretched between a drive pulley rotationally driven by a main scanning motor and a driven pulley. The timing belt is secured to the carriage 98. The carriage 98 is reciprocally moved by forward and reverse rotations of the main scanning motor.

In order to convey a sheet 92 set in the sheet feeding cassette 93 to the lower side of the liquid discharge heads 1, the inkjet recording apparatus 90 includes a sheet feeding roller 105 and a friction pad 106 to separate and feed the sheet 92 from the sheet feeding cassette 93, a guide member 107 to guide the sheet 92, a conveyance roller 108 to turn and convey the fed sheet 92, a conveyance roller 109 (i.e., a conveyor) pressed against the circumferential surface of the conveyance roller 108, and a leading end roller 118 to define the feed angle of the sheet 92 from the conveyance roller 108. The conveyance roller 108 is rotationally driven by a sub-scanning motor via a gear train.

The inkjet recording apparatus 90 further includes a print receiver 111 disposed below the liquid discharge heads 1. The print receiver 111 is a sheet guide to guide the sheet 92, which is fed from the conveyance roller 108, in a range corresponding to a range of movement of the carriage 98 in the main scanning direction. A conveyance roller 112 and a spur roller 113 are disposed on the downstream side of the print receiver 111 in the sheet conveyance direction. The conveyance roller 112 is driven to rotate so as to feed the sheet 92 in a sheet ejection direction. The inkjet recording apparatus 90 further includes a sheet ejection roller 114 and a spur roller 115 to feed the sheet 92 to the sheet ejection tray 95 and guides 116 and 117 that define a sheet ejection passage.

At the time of recording, the inkjet recording apparatus 90 drives the liquid discharge heads 1 in response to an image signal while moving the carriage 98 to discharge ink onto the sheet 92, which is stopped below the liquid discharge heads 1, to record one line of a desired image on the sheet 92. After that, the sheet 92 is conveyed by a predetermined amount, and then the next line of the desired image is recorded on the sheet 92. In response to a recording end signal or a signal indicating that the trailing end of the sheet 92 has reached a recording area, the inkjet recording apparatus 90 ends the recording operation and ejects the sheet 92.

The inkjet recording apparatus 90 further includes a recovery device to recover the liquid discharge heads 1 from discharge failure. The recovery device is disposed outside the recording area at the right end in the direction of movement of the carriage 98. The recovery device includes a cap unit, a suction unit, and a cleaning unit. On standby for printing, the carriage 98 is placed on the side on which the recovery device is disposed, and the liquid discharge heads 1 are capped with the cap unit. Accordingly, the discharge ports are maintained in a wet state, thus preventing discharge failure due to ink drying. In addition, during recording, the inkjet recording apparatus 90 discharges ink not relating to the recording to maintain the viscosity of ink in all the discharge ports constant, thus maintaining a stable discharge state.

For example, when the discharge failure occurs, the discharge ports (nozzles) of the liquid discharge heads 1 are sealed with the cap unit, and bubbles along with ink are sucked from the discharge ports by the suction unit through a tube. Thus, the recovery device removes ink and dust adhered to the surface on which the discharge ports are disposed to recover the liquid discharge head 1 from the discharge failure. The sucked ink is drained to a waste ink container disposed at a lower portion of the apparatus body, and is absorbed into and retained in an ink absorber in the waste ink container.

As described above, the inkjet recording apparatus 90 mounts the liquid discharge head 1 including the above-described actuator. Thus, stable ink discharge characteristics are obtained to enhance image quality.

The liquid discharge head 1 used in the inkjet recording apparatus 90 has been described above. In some embodiments, for example, the liquid discharge head 1 may be applied to an apparatus that discharges droplets other than ink, for example, a liquid resist for patterning.

Applied cases of the actuator or the liquid discharge apparatus including the actuator according to the above-described embodiments will be described below.

### First Applied Case: Electrode Manufacturing Apparatus

The liquid discharge apparatus according to an embodiment of the present disclosure may also include an apparatus for manufacturing an electrode and an electrochemical element that is also referred to as an electrode manufacturing apparatus. The electrode manufacturing apparatus is described below.

FIG. 10 is a schematic view of an electrode manufacturing apparatus as a liquid discharge apparatus according to a first applied case. The electrode manufacturing apparatus is an apparatus for manufacturing an electrode including a layer containing an electrode material by discharging a liquid composition using a head module including a liquid discharge head.

### Device for Forming Layer Containing Electrode Material and Process of Forming Layer Containing Electrode Material

A discharge device in the electrode manufacturing apparatus illustrated in FIG. 10 is the head module according to the above-described embodiments of the present disclosure. The liquid discharge head of the head module discharges a liquid composition. By so doing, the liquid composition is applied onto an object, and a liquid composition layer is formed on the object. The object, which may also be referred to as a discharge target in the following description, is not limited and may be appropriately selected depending on the intended purpose, as long as the object is an object on which a layer containing an electrode material is to be formed. Examples of the object include an electrode substrate, i.e., a current collector, an active material layer, and a layer containing a solid electrode material. The object may be an electrode composite layer containing an active material on an electrode substrate, i.e., a current collector. The discharge device and a discharge process may be a device and a process of forming a layer containing an electrode material by directly discharging a liquid composition as long as the layer containing an electrode material can be formed on a discharge target. The discharge device and the discharge process may be a device and a process of forming a layer containing an electrode material by indirectly discharging a liquid composition.

### Other Devices and Other Processes

Other configurations included in the electrode manufacturing apparatus for manufacturing an electrode composite layer are not limited to any particular configuration and may be appropriately selected depending on the intended purpose, as long as the effects of the present embodiment are not impaired. Other processes included in the method for manufacturing an electrode composite layer are not limited to any particular process and may be appropriately selected depending on the intended purpose, as long as the effects of the present embodiment are not impaired. For example, a heating device and a heating process are examples of the configuration and the process included in the electrode manufacturing apparatus and the manufacturing method of the electrode composite layer.

### Heating Device and Heating Process

The heating device included the electrode manufacturing apparatus for manufacturing an electrode composite layer is a device that heats the liquid composition discharged by the discharge device. The heating process included in the manufacturing method for manufacturing an electrode composite layer is a process of heating the liquid composition discharged in the discharge process. The liquid composition is heated to dry the liquid composition layer.

### Structure to Form Layer Containing Electrode Material by Direct Discharge of Liquid Composition

As an example of the electrode manufacturing apparatus, an electrode manufacturing apparatus that forms an electrode composite layer containing an active material on an electrode substrate, i.e., a current collector, is described below. As illustrated in FIG. 10, the electrode manufacturing apparatus includes a discharge process device 110 and a heating process device 120. The discharge process device 110 (i.e., a liquid discharge unit) performs a discharge process of applying a liquid composition onto a print base material 704 having a discharge target to form a liquid composition layer. The heating process device 120 performs a heating process of heating the liquid composition layer to obtain an electrode composite layer.

The electrode manufacturing apparatus includes a conveyor 705 (i.e., a conveyor) that conveys the print base material 704 (i.e., a medium). The conveyor 705 conveys the print base material 704 to the discharge process device 110 and the heating process device 120 in this order at a preset speed. A method of producing the print base material 704 having the discharge target such as an active material layer is not limited to any particular method, and a known method can be appropriately selected. The discharge process device 110 includes the liquid discharge head 1 that performs an application process of applying the liquid composition onto the print base material 704, a storage container 281b that stores a liquid composition 707, and a supply tube 281c that supplies the liquid composition 707 stored in the storage container 281b to the liquid discharge head 1.

The discharge process device 110 discharges the liquid composition 707 from the liquid discharge head 1 so that the liquid composition 707 is applied onto the print base material 704 to form a liquid composition layer in a thin film shape. The storage container 281b may be integrated with the electrode manufacturing apparatus that forms the electrode composite layer or may be detachable from the electrode manufacturing apparatus. The storage container 281b may be a container additionally attachable to a container integrated with the electrode manufacturing apparatus for manufacturing the electrode composite layer or to a container detachable from the electrode manufacturing apparatus for manufacturing the electrode composite layer. The storage container 281b that stably stores the liquid composition 707 and the supply tube 281c that stably supplies the liquid composition 707 can be used.

The heating process device 120 performs a solvent removal process of heating and removing the solvent remaining in the liquid composition layer. Specifically, the solvent that remains in the liquid composition layer is heated and dried by a heating device 706 of the heating process device 120. Accordingly, the solvent is removed from the liquid composition layer. Thus, the electrode composite layer is formed. The heating process device 120 may perform the solvent removing process under reduced pressure.

The heating device 706 is not limited to any particular heater and may be appropriately selected depending on the intended purpose. For example, the heating device 706 may be a substrate heater, an infrared (IR) heater, or a hot air heater. The heating device 706 may be a combination of at least two of the substrate heater, the IR heater, and the hot air heater. A heating temperature and heating time can be appropriately selected according to the boiling point of the solvent contained in the liquid composition 707 or the thickness of a formed film.

The electrode manufacturing apparatus according to the present embodiment is used to discharge the liquid composition to a desired position on the discharge target. The electrode composite layer can be suitably used, for example, as a part of the configuration of an electrochemical element. The configuration of the electrochemical element other than the electrode composite layer is not limited to any particular configuration, and a known configuration can be appropriately selected. Examples of the configuration other than the electrode composite layer include a positive electrode, a negative electrode, and a separator.

### Second Applied Case: Ultrasonic Diagnostic Apparatus

An applied case of the actuator is described below. The actuator according to the embodiment is not limited to an apparatus that discharges liquid, and, for example, may be used for emitting ultrasonic waves. An ultrasonic diagnostic apparatus to which the actuator according to the above embodiments is applied is described below.

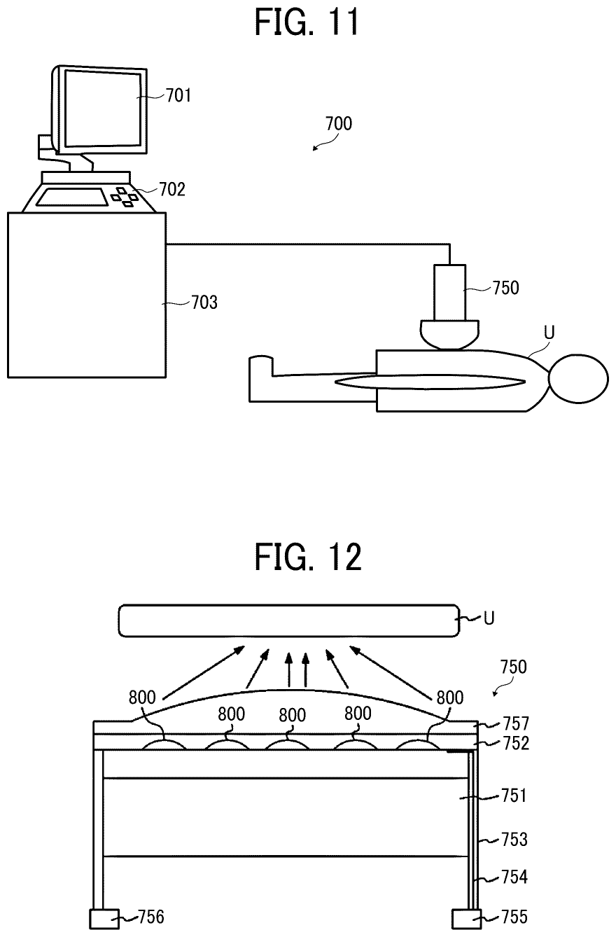

FIG. 11 is a schematic view of an ultrasonic diagnostic apparatus to which the actuator according to the above embodiments is applied.

An ultrasonic diagnostic apparatus 700 includes an ultrasonic probe 750. The ultrasonic probe 750 emits ultrasonic waves toward a measurement target U and detects vibration of the ultrasonic waves reflected by the measurement target U. The ultrasonic diagnostic apparatus 700 also includes a display 701 that visualizes and displays a signal from the ultrasonic probe 750, a control panel 702, and a controller 703 that controls the ultrasonic probe 750.

Typically, the controller 703 includes an ultrasonic pulse generator, a converter, and an ultrasonic image forming unit. The ultrasonic pulse generator generates a pulsed electrical signal for generating an ultrasonic signal. The converter converts an echo signal received from the ultrasonic probe 750 into an electrical signal. The ultrasonic image forming unit generates a two-dimensional or three-dimensional ultrasonic image, or various Doppler images from echo signals.

The display 701 is, for example, a liquid crystal display (LCD) or a monitoring device and displays an image generated by the controller 703. The control panel 702 is an input device for an operator to input, for example, parameters so as to appropriately diagnose the measurement target U. The control panel 702 may include, for example, a push button and a touch panel.

The ultrasonic probe 750 is electrically connected to the controller 703 via, for example, a cable. The ultrasonic probe 750 emits the ultrasonic signal toward the measurement target U which is a human body or an object and receives the ultrasonic signal reflected as an echo from the measurement target U. Thus, the ultrasonic diagnostic apparatus 700 can visualize an inside of the measurement target U and diagnosis the inside by emitting and receiving an ultrasonic signal.

FIG. 12 is a schematic diagram illustrating a configuration of the ultrasonic probe 750 of the ultrasonic diagnostic apparatus 700 illustrated in FIG. 11.

The ultrasonic probe 750 includes a support board 751, a piezoelectric micro-machined ultrasonic transducer (PMUT) chip 752 which is an ultrasonic transducer disposed on the support board 751, a flexible printed board 753, wiring 754, connectors 755 and 756, and an acoustic lens 757. The PMUT chip 752 is electrically connected to the connectors 755 and 756 via the flexible printed board 753 and the wiring 754, and the connectors 755 and 756 are connected to the controller 703 via a circuit board. The support board 751 functions as a backing plate to support the PMUT chip 752.

The acoustic lens 757 is made of silicon resin and used for focusing the ultrasonic waves emitted from the PMUT chip 752 on the measurement position of the measurement target U. The acoustic lens 757 has a so-called dome shape in which the central portion is thicker than the peripheral portion. The acoustic lens 757 tightly contacts the measurement target U and deflects the ultrasonic waves in a pseudo manner due to the difference in thickness between the central portion and the peripheral portion to focus the ultrasonic waves. The acoustic lens 757 has a function of focusing ultrasonic waves in at least one direction and does not necessarily focus the ultrasonic waves to one point. The acoustic lens 757 and the PMUT chip 752 are bonded to each other by, for example, an adhesive. The PMUT chip 752 includes the array of multiple actuators 800. The actuator 800 is described below in detail.

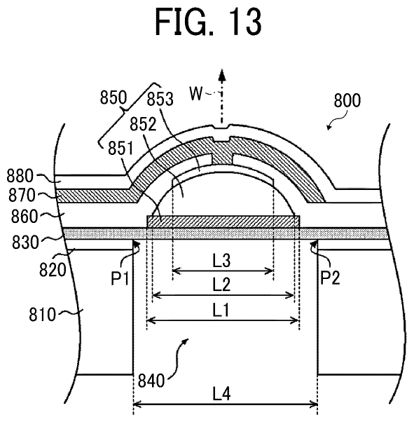

FIG. 13 is a cross-sectional view of the actuator 800 in the ultrasonic probe 750 illustrated in FIG. 12.

The actuator 800 includes a silicon substrate 810, a wiring 820, a vibration film 830, a piezoelectric element 850, an insulating film 860, a lead 870, and a protective film (moisture-proof film) 880. A void space 840, which is an opening having, for example, a cylindrical shape, is formed in the silicon substrate 810, and the wiring 820 is laminated over the silicon substrate 810.

The wiring 820 is formed over the silicon substrate 810 and includes a wiring for applying a voltage to a first electrode 851 and a wiring for applying a voltage to a second electrode 853. The vibration film 830 as the diaphragm member is laminated over the wiring 820.

The vibration film 830 is formed over the wiring 820. As the vibration film 830 receives vibrations from the piezoelectric element 850, the vibration film 830 is displaced in the vertical direction in FIG. 13. The piezoelectric element 850 over the vibration film 830 includes the first electrode 851, a piezoelectric body 852, and the second electrode 853. The first electrode 851 may be referred to as a lower electrode, and the second electrode 853 may be referred to as an upper electrode.

The first electrode 851 has a width L1 (outer diameter) which is smaller than a width L4 (inner diameter) of the void space 840 formed in the silicon substrate 810, and has an outer shape that fits inside the void space 840. The second electrode 853 is formed along a dome-shaped upper face of the piezoelectric body 852.

A width L3 (outer diameter) of the second electrode 853 is preferably smaller than a width L2 (outer diameter) of the piezoelectric body 852. In particular, when the piezoelectric body 852 has a dome shape, the width L3 of the second electrode 853 is smaller than the outer shape of the piezoelectric body 852. As a result, a short circuit between the second electrode 853 and the first electrode 851 can be prevented.

The insulating film 860 prevents a short circuit between the first electrode 851 and the second electrode 853 and a short circuit between the lead 870 and the first electrode 851. In the present embodiment, the piezoelectric body 852 has, but is not limited to, the dome shape. The shape of the piezoelectric body 852 may be a shape other than the dome shape, such as a cylindrical shape.

With the above-described configuration, the piezoelectric body 852 is mechanically deformed by application of a drive voltage between the first electrode 851 and the second electrode 853. By causing periodic fluctuations in the drive voltage, a vibration of a predetermined frequency can be generated. As a result, the vibration film 830 is vibrated to generate ultrasonic waves W.

Further, as ultrasonic waves vibrate the piezoelectric body 852, the piezoelectric body 852 is polarized to generate a potential difference between the first electrode 851 and the second electrode 853. Thus, the actuator 800 also functions as a detector to detect the vibrations as an electrical signal. As described above, the actuator 800 functions as an electromechanical transducer element that periodically expands and contracts the piezoelectric body 852 by a potential difference, which is an electrical signal, between the first electrode 851 and the second electrode 853, to generate vibrations. In particular in the present embodiment, the actuator 800 functions as an ultrasonic transducer that generates a sound wave in an ultrasonic range with vibrations.

In the actuator 800 having the above-described configuration, portions of the vibration film 830 near the fixed ends P1 and P2 are easily movable since the first electrode 851 has an outer shape that fits inside the void space 840. As a result, the vibration film 830 can be sufficiently vibrated. The deformation efficiency of the vibration film 830 with respect to voltage increases, and the responsiveness to high frequency is not reduced.

In the above-described embodiments, the “liquid discharge apparatus” includes the liquid discharge head or a liquid discharge unit (may be referred to simply as a “unit”) and drives the liquid discharge head to discharge liquid. The liquid discharge apparatus may be, for example, any apparatus that can discharge liquid to a medium onto which liquid can adhere or any apparatus to discharge liquid toward gas or into a different liquid.

The “liquid discharge apparatus” may further include devices relating to feeding, conveying, and ejecting of the medium onto which liquid can adhere and also include, for example, a pretreatment device and an aftertreatment device. The “liquid discharge apparatus” may be, for example, an image forming apparatus to form an image on a sheet by discharging ink, or a three-dimensional fabrication apparatus to discharge fabrication liquid to a powder layer in which powder material is formed in layers, so as to form a three-dimensional object.

The “liquid discharge apparatus” is not limited to an apparatus that discharges liquid to visualize meaningful images such as letters or figures. For example, the liquid discharge apparatus may be an apparatus that forms patterns having no meaning or an apparatus that fabricates three-dimensional images.

The above-described term “medium onto which liquid can adhere” represents a medium on which liquid is at least temporarily adhered, a medium on which liquid is adhered and fixed, or a medium into which liquid adheres and permeates. Specific examples of the “medium onto which liquid can adhere” include, but are not limited to, a recording medium (medium) such as a paper sheet, recording paper, a recording sheet of paper, a film, or cloth, an electronic component such as an electronic substrate or a piezoelectric element, and a medium such as layered powder, an organ model, or a testing cell. The “medium onto which liquid can adhere” includes any medium to which liquid adheres, unless otherwise specified.

Examples of materials of the “medium onto which liquid can adhere” include any materials to which liquid can adhere even temporarily, such as paper, thread, fiber, fabric, leather, metal, plastic, glass, wood, ceramic, construction materials such as wallpaper or floor material, cloth textile, a current collector such as an aluminum foil or a copper foil, and an electrode in which an active material layer is formed on the current collector.

Further, the term “liquid” is not limited to a particular liquid and includes any liquid having a viscosity or a surface tension that can be discharged from the head. However, preferably, the viscosity of the liquid is not greater than 30 millipascal-second (mPa s) under ordinary temperature and ordinary pressure or by heating or cooling. Examples of the liquid include a solution, a suspension, or an emulsion that contains, for example, a solvent, such as water or an organic solvent; a colorant, such as dye or pigment; a functional material, such as a polymerizable compound, a resin, or a surfactant; a biocompatible material, such as deoxyribonucleic acid (DNA), amino acid, protein, or calcium; an edible material, such as a natural colorant; an active material and a solid electrolyte used as an electrode material; or ink containing a conductive material or an insulating material. Such a solution, a suspension, or an emulsion can be used for, e.g., inkjet ink, surface treatment solution, a liquid for forming components of electronic element or light-emitting element or a resist pattern of electronic circuit, a material solution for three-dimensional fabrication, an electrode, or an electrochemical element.

Examples of the liquid include ink, treatment liquid, DNA sample, resist, pattern material, binder, fabrication liquid, and solution or liquid dispersion containing amino acid, protein, or calcium.

The liquid discharge apparatus may be an apparatus to move the liquid discharge head and the medium onto which liquid can adhere relative to each other. However, the liquid discharge apparatus is not limited to such an apparatus. For example, the liquid discharge apparatus may be a serial head apparatus that moves the liquid discharge head or a line head apparatus that does not move the liquid discharge head.

Examples of the liquid discharge apparatus further include: a treatment liquid applying apparatus that discharges a treatment liquid onto a sheet to apply the treatment liquid to the surface of the sheet, for reforming the surface of the sheet; and an injection granulation apparatus that injects a composition liquid, in which a raw material is dispersed in a solution, through a nozzle to granulate fine particle of the raw material.

The “liquid discharge apparatus” is not limited to a stationary apparatus. The liquid discharge apparatus may be, for example, a robot which is equipped with a liquid discharge head and movable by remote control or autonomous driving. The movable robot can paint an outer wall of a building and paint a road marking (e.g., a crosswalk, a stop line, and a speed limit) on a road. In this case, a building and a road are also included in the “medium onto which liquid can adhere.”

The “liquid discharge unit” refers to a liquid discharge head integrated with functional components or mechanisms, i.e., an assembly of components related to liquid discharge. For example, the “liquid discharge unit” includes a combination of the liquid discharge head with at least one of a head tank, a carriage, a supply mechanism, a maintenance mechanism, or a main-scanning moving mechanism.

The above integration may be achieved by, for example, a combination in which the liquid discharge head and a functional component(s) or mechanism(s) are fixed to each other through, e.g., fastening, bonding, or engaging, and a combination in which one of the liquid discharge head and the functional component(s) or mechanism(s) is movably held to the other. The liquid discharge head and the functional component(s) or mechanism(s) may be detachably attached to each other.

The pressure generator used in the liquid discharge head is not limited to a particular type of pressure generator. The pressure generator is not limited to the piezoelectric actuator (or a laminated-type piezoelectric element) described in the above-described embodiments, and may be, for example, a thermal actuator that employs a thermoelectric transducer element, such as a thermal resistor, or an electrostatic actuator including a diaphragm and opposed electrodes.

In the present specification, the terms “image formation,” “recording,” “printing,” “image printing,” and “fabricating” used herein may be used synonymously with each other.

Aspects of the present disclosure are, for example, as follows.

### Aspect 1

An actuator includes a substrate, a frame, and a projection. The substrate includes a diaphragm, a piezoelectric body to generate driving force, and two electrodes (e.g., a first electrode and a second electrode) to cause the piezoelectric body to generate the driving force. The frame is bonded to the substrate to hold the substrate. The projection restricts a distance between the substrate and the frame. The projection is disposed on at least one of a bonding face of the substrate or a bonding face of the frame to be bonded to each other. The distance varies toward a periphery of the frame.

### Aspect 2

In the actuator according to Aspect 1, the projection is formed such that the distance varies in at least one of a first direction of the actuator or a second direction of the actuator intersecting the first direction (e.g., in at least one of a longitudinal direction or a transverse direction).

In other words, an actuator includes a substrate, a frame, and a projection. The substrate has a first bonding face. The substrate includes a diaphragm, a piezoelectric body over the diaphragm to generate driving force to vibrate the diaphragm, and at least two electrodes sandwiching the piezoelectric body to apply voltage to the piezoelectric body to generate the driving force. The frame has a second bonding face bonded to the first bonding face of the substrate in a bonding direction to hold the substrate. The projection projects in the bonding direction from at least one of the first bonding face or the second bonding face to restrict a distance between the first bonding face of the substrate and the second bonding face of the frame. The projection has a height in the bonding direction. The height of the projection varies toward a periphery of the frame in at least one of a longitudinal direction of the substrate orthogonal to the bonding direction or a transverse direction orthogonal to the longitudinal direction and the bonding direction.

### Aspect 3

In the actuator according to Aspect 1 or 2, the projection includes multiple projections with the distance that varies stepwise.

In other words, the actuator according to Aspect 1 or 2, further includes multiple projections including the projection. The height of the projection varies stepwise toward the periphery of the frame in at least one of the longitudinal direction or the transverse direction.

### Aspect 4

In the actuator according to Aspect 1 or 2, the projection has at least one of a tapered shape, a curved shape, or a stepwise shape.

In other words, the projection has one of a tapered shape, a curved shape, or a stepwise shape.

### Aspect 5

In the actuator according to any one of Aspects 1 to 4, the projection is disposed on both the substrate and the frame. The projection of the substrate and the projection of the frame are fitted to each other to bond the substrate and the frame. Alternatively, the projection of the substrate is bonded to the bonding face of the frame and the projection of the frame is bonded to the bonding face of the substrate to bond the substrate and the frame

In other words, the projection includes a first projection projecting from the first bonding face of the substrate and a second projection projecting from the second bonding face of the frame. The first projection is fitted to the second projection to bond the substrate and the frame.

Alternatively, the projection includes a first projection projecting from the first bonding face of the substrate and a second projection projecting from the second bonding face of the frame. The first projection of the substrate is bonded to the second projection of the frame to bond the substrate and the frame.

### Aspect 6

A liquid discharge head includes the actuator according to any one of Aspects 1 to 5, and the actuator further includes a pressure chamber to generate pressure and a nozzle to discharge a liquid droplet.

In other words, a liquid discharge head includes a nozzle substrate having a nozzle and the actuator according to any one of Aspects 1 to 5, having a pressure chamber facing the diaphragm. The actuator pressurizes a liquid in the pressure chamber to discharge the liquid in the pressure chamber from the nozzle.

### Aspect 7

A unit includes the liquid discharge head according to Aspect 6.

In other words, a liquid discharge unit includes the liquid discharge head according to Aspect 6 and a carriage mounting the liquid discharge head to move the liquid discharge head.

### Aspect 8

A liquid discharge apparatus includes the unit according to Aspect 7.

In other words, a liquid discharge apparatus includes the liquid discharge unit according to Aspect 7, to discharge a liquid onto a medium and a conveyor to convey the medium to the liquid discharge head.

### Aspect 9

An ultrasonic diagnostic apparatus includes the actuator according to any one of Aspects 1 to 5.

In other words, an ultrasonic diagnostic apparatus includes an ultrasonic probe to emit an ultrasonic signal. The ultrasonic probe includes multiple actuators including the actuator according to Aspects 1 to 5.

### Aspect 10

An actuator includes a substrate and a frame. The substrate has a first bonding face. The substrate includes a diaphragm, a piezoelectric body over the diaphragm to generate driving force to vibrate the diaphragm, and two electrodes sandwiching the piezoelectric body to apply voltage to the piezoelectric body to generate the driving force. The frame has a second bonding face bonded to the first bonding face of the substrate in a bonding direction to hold the substrate. At least one of the first bonding face or the second bonding face has a curved shape.

### Aspect 11

An actuator includes a substrate and a frame. The substrate has a first bonding face. The substrate includes a diaphragm, a piezoelectric body over the diaphragm to generate driving force to vibrate the diaphragm, and two electrodes sandwiching the piezoelectric body to apply voltage to the piezoelectric body to generate the driving force. The frame has a second bonding face bonded to the first bonding face of the substrate in a bonding direction to hold the substrate. At least one of the first bonding face or the second bonding face has multiple sloped shapes.

### Aspect 12

In the actuator according to Aspect 10, the curved shape is formed on the frame and projects toward the substrate in the bonding direction. The curved shape has a height in the bonding direction, and the height of the curved shape varies toward a periphery of the frame in at least one of a longitudinal direction of the substrate orthogonal to the bonding direction or a transverse direction orthogonal to the longitudinal direction and the bonding direction.

### Aspect 13

In the actuator according to Aspect 11, the multiple sloped shapes are formed on the frame and project toward the substrate in the bonding direction. Each of the multiple sloped shapes has a height in the bonding direction. The height of each of the multiple sloped shapes varies toward a periphery of the frame in at least one of a longitudinal direction of the substrate orthogonal to the bonding direction or a transverse direction orthogonal to the longitudinal direction and the bonding direction.

### Aspect 14

In the actuator according to Aspect 1, the height of the projection in a central portion of the frame is a first height. The height of the projection in an outer portion adjacent to the periphery of the frame is a second height different from the first height. A distance between the substrate and the frame at the central portion and the outer portion are different from a distance between the substrate and the frame at another portion excluding the central portion and the outer portion.

### Aspect 15

In the actuator according to Aspect 14, each of the first height and the second height is different from the height of the projection in other portions of the frame other than the central portion and the outer portion adjacent to the periphery to prevent the substrate from warping.

### Aspect 16

In the actuator according to Aspect 12, the height of the curved shape in a central portion of the frame is a first height. The height of the curved shape in a portion adjacent to the periphery of the frame is a second height different from the first height. Each of the first height and the second height is different from the height of the curved shape in other portions of the frame other than the central portion and the portion adjacent to the periphery to prevent the substrate from warping.

### Aspect 17

In the actuator according to Aspect 13, the height of each of the multiple sloped shapes in a central portion of the frame is a first height. The height of each of the multiple sloped shapes in a portion adjacent to the periphery of the frame is a second height different from the first height. Each of the first height and the second height is different from the height of each of the multiple sloped shapes in other portions of the frame other than the central portion and the portion adjacent to the periphery to prevent the substrate from warping.

### Aspect 18

An ultrasonic diagnostic apparatus includes an ultrasonic probe to emit an ultrasonic signal. The ultrasonic probe includes multiple actuators including the actuator according to Aspect 1 or 2.

### Aspect 19

An ultrasonic diagnostic apparatus includes an ultrasonic probe to emit an ultrasonic signal. The ultrasonic probe includes multiple actuators including the actuator according to Aspect 12.

### Aspect 20

An ultrasonic diagnostic apparatus includes an ultrasonic probe to emit an ultrasonic signal. The ultrasonic probe includes multiple actuators including the actuator according to Aspect 13.

As described above, according to one aspect of the present disclosure, when a substrate including a diaphragm and having a function of vibrating the diaphragm is bonded to a different component, the warpage of the substrate can be controlled.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention

1. An actuator comprising:
a substrate having a first bonding face, the substrate including:
a diaphragm;
a piezoelectric body over the diaphragm to generate driving force to vibrate the diaphragm; and
at least two electrodes sandwiching the piezoelectric body to apply voltage to the piezoelectric body to generate the driving force;
a frame having a second bonding face bonded to the first bonding face of the substrate in a bonding direction to hold the substrate; and
a projection projecting in the bonding direction from at least one of the first bonding face or the second bonding face to restrict a distance between the first bonding face of the substrate and the second bonding face of the frame,
wherein the projection has a height in the bonding direction, and
the height of the projection varies toward a periphery of the frame in at least one of a longitudinal direction of the substrate orthogonal to the bonding direction or a transverse direction orthogonal to the longitudinal direction and the bonding direction.

2. The actuator according to claim 1, further comprising multiple projections including the projection,
wherein the height of the projection varies stepwise toward the periphery of the frame in at least one of the longitudinal direction or the transverse direction.

3. The actuator according to claim 1,
wherein the projection has one of:
a tapered shape;
a curved shape; and
a stepwise shape.

4. The actuator according to claim 1,
wherein the projection includes:
a first projection projecting from the first bonding face of the substrate; and
a second projection projecting from the second bonding face of the frame, and
wherein the first projection is fitted to the second projection to bond the substrate and the frame.

5. The actuator according to claim 1,
wherein the projection includes:
a first projection projecting from the first bonding face of the substrate; and
a second projection projecting from the second bonding face of the frame and facing the first projection, and
wherein the first projection of the substrate is bonded to the second projection of the frame to bond the substrate and the frame.

6. A liquid discharge head comprising:
a nozzle substrate having a nozzle; and
the actuator according to claim 1, having a pressure chamber facing the diaphragm, the actuator to pressurize a liquid in the pressure chamber to discharge the liquid in the pressure chamber from the nozzle.

7. A liquid discharge unit comprising:
the liquid discharge head according to claim 6; and
a carriage mounting the liquid discharge head to move the liquid discharge head.

8. A liquid discharge apparatus comprising the liquid discharge unit according to claim 7, to discharge a liquid onto a medium; and
a conveyor to convey the medium to the liquid discharge head.

9. An ultrasonic diagnostic apparatus comprising:
an ultrasonic probe to emit an ultrasonic signal, the ultrasonic probe including multiple actuators including the actuator according to claim 1.

10. An actuator comprising:
a substrate having a first bonding face, the substrate including:
a diaphragm;
a piezoelectric body over the diaphragm to generate driving force to vibrate the diaphragm; and
two electrodes sandwiching the piezoelectric body to apply voltage to the piezoelectric body to generate the driving force;
a frame having a second bonding face bonded to the first bonding face of the substrate in a bonding direction to hold the substrate,
at least one of the first bonding face or the second bonding face having a curved shape.

11. An actuator comprising:
a substrate having a first bonding face, the substrate including:
a diaphragm;
a piezoelectric body over the diaphragm to generate driving force to vibrate the diaphragm; and
two electrodes sandwiching the piezoelectric body to apply voltage to the piezoelectric body to generate the driving force;
a frame having a second bonding face bonded to the first bonding face of the substrate in a bonding direction to hold the substrate,
at least one of the first bonding face or the second bonding face having multiple sloped shapes.

12. The actuator according to claim 10,
wherein the curved shape is formed on the frame and projects toward the substrate in the bonding direction,
the curved shape has a height in the bonding direction, and
the height of the curved shape varies toward a periphery of the frame in at least one of a longitudinal direction of the substrate orthogonal to the bonding direction or a transverse direction orthogonal to the longitudinal direction and the bonding direction.

13. The actuator according to claim 11,
wherein the multiple sloped shapes are formed on the frame and project toward the substrate in the bonding direction,
each of the multiple sloped shapes has a height in the bonding direction, and
the height of each of the multiple sloped shapes varies toward a periphery of the frame in at least one of a longitudinal direction of the substrate orthogonal to the bonding direction or a transverse direction orthogonal to the longitudinal direction and the bonding direction.

14. The actuator according to claim 1,
wherein the height of the projection in a central portion of the frame is a first height,
the height of the projection in an outer portion adjacent to the periphery of the frame is a second height different from the first height, and
a distance between the substrate and the frame at the central portion and the outer portion are different from a distance between the substrate and the frame at another portion excluding the central portion and the outer portion.

15. The actuator according to claim 14,
wherein each of the first height and the second height is different from the height of the projection in other portions of the frame other than the central portion and the outer portion adjacent to the periphery to prevent the substrate from warping.

16. The actuator according to claim 12,
wherein the height of the curved shape in a central portion of the frame is a first height,
the height of the curved shape in a portion adjacent to the periphery of the frame is a second height different from the first height, and
each of the first height and the second height is different from the height of the curved shape in other portions of the frame other than the central portion and the portion adjacent to the periphery to prevent the substrate from warping.

17. The actuator according to claim 13,
wherein the height of each of the multiple sloped shapes in a central portion of the frame is a first height,
the height of each of the multiple sloped shapes in a portion adjacent to the periphery of the frame is a second height different from the first height, and
each of the first height and the second height is different from the height of each of the multiple sloped shapes in other portions of the frame other than the central portion and the portion adjacent to the periphery to prevent the substrate from warping.

18. An ultrasonic diagnostic apparatus comprising:
an ultrasonic probe to emit an ultrasonic signal, the ultrasonic probe including multiple actuators including the actuator according to claim 2.

19. An ultrasonic diagnostic apparatus comprising:
an ultrasonic probe to emit an ultrasonic signal, the ultrasonic probe including multiple actuators including the actuator according to claim 12.

20. An ultrasonic diagnostic apparatus comprising:
an ultrasonic probe to emit an ultrasonic signal, the ultrasonic probe including multiple actuators including the actuator according to claim 13.
